(19) United States
(12) Patent Application Publication
(10) Pub. No.: US 2025/0379419 A1
(43) Pub. Date: Dec. 11, 2025

(54) WAVELENGTH TUNABLE LASER, WAVELENGTH TUNABLE LASER MODULE, AND METHOD OF MANUFACTURING LAYER STRUCTURE OF WAVELENGTH TUNABLE LASER

(71) Applicant: NTT, INC., Tokyo (JP)

(72) Inventors: Yuta Ueda, Tokyo (JP); Takahiko Shindo, Tokyo (JP); Makoto Shimokozono, Tokyo (JP)

(21) Appl. No.: 18/876,955

(22) PCT Filed: Jun. 23, 2022
(86) PCT No.: PCT/JP2022/025048

§ 371 Date: Dec. 19, 2024

(51) Int. Cl. H01S 5/0625; H01S 5/02345; H01S 5/042; H01S 5/10; H01S 5/125; H01S 5/343

(52) U.S. Cl. CPC H01S 5/06256; H01S 5/02345; H01S 5/04256; H01S 5/1028; H01S 5/1096; H01S 5/125; H01S 5/34313; H01S 5/3438

(57) ABSTRACT

A wavelength-tunable laser includes a substrate, a waveguide layer over the substrate, and a cladding over the waveguide layer. The wavelength-tunable laser further includes an active layer in a part of the waveguide layer, and a tunable wavelength filter in at least one end region of the waveguide layer in a direction along which light is to be guided.

### CROSS-REFERENCE TO RELATED APPLICATIONS

This application is a national phase entry of PCT Application No. PCT/JP2022/025048, filed on Jun. 23, 2022, which application is hereby incorporated herein by reference.

### TECHNICAL FIELD

The present invention relates to a wavelength-tunable laser that improves light output characteristics and a method of manufacturing a layer structure thereof.

### BACKGROUND

Since a wavelength-tunable laser is used in a wide application range such as a carrier wave light source for optical communication and gas sensing, it is important to achieve both a wavelength range and a light output that can be covered by one light source.

In gas sensing, the presence or absence (concentration), temperature, and pressure of a gas are measured by utilizing the fact that a target gas has a light absorption spectrum unique to the gas. That is, by continuously sweeping a wavelength of light from the wavelength-tunable laser, a state of the gas is detected from the light absorption intensity in the vicinity of a specific wavelength or a width of an absorption curve. Therefore, in order to detect many absorption lines, a width of the wavelength range that can be output by the wavelength-tunable laser is important.

On the other hand, in the case of spatially measuring a target such as gas concentration distribution, it is necessary to cause a plurality of laser beams to enter a target space. In order to realize a plurality of laser beams, a method using a plurality of wavelength-tunable lasers is conceivable. However, a control circuit for synchronously controlling different wavelength-tunable lasers becomes complicated. On the other hand, a plurality of laser beams can be acquired by branching light output by an appropriate demultiplexer by using a single wavelength-tunable laser. According to this method, a complicated control circuit is unnecessary. In this case, the light output is attenuated as the laser light output is branched. Therefore, light intensity that can be output from a single wavelength-tunable laser is also important.

As illustrated in FIG. 8A, a conventional wavelength-tunable laser 40 includes an optical gain region 41, a phase adjustment region 42, and at least one tunable wavelength filter (TWF) 43, and has a form of an optical resonator. With this configuration, light generated/amplified in the optical gain region 41 resonates in an optical waveguide (in the drawing, an arrow 44).

In the conventional wavelength-tunable laser 40, as illustrated in FIG. 8B, specific wavelengths (hereinafter, referred to as “resonance modes”) 51_1, 51_2, and 51_3 corresponding to an optical path length of the resonator exist in the optical resonator. The single resonance mode 51_1 among the resonance modes 51_1, 51_2, and 51_3 is selected by the tunable wavelength filter 43 (wavelength spectrum 52). The wavelength of the resonance mode 51_1 is finely adjusted by changing a refractive index of the phase adjustment region 42, that is, finely adjusting an optical path length of the resonator (in the drawing, an arrow 53). Thus, the single-mode wavelength-tunable laser is operated.

For example, for CO₂ gas sensing, a distributed Bragg reflector (DBR) laser having an oscillation wavelength in a 2 μm band using an InP-based semiconductor is disclosed (Non Patent Literature 1).

The DBR laser includes a DBR region as a TWF. A material of bulk InGaAs lattice-matched with InP is used for the DBR region or the phase adjustment region (hereinafter, referred to as a “tuning region”). Here, “bulk” indicates a material (crystal) having a thickness of several 100 nm or more. By injecting a current into the tuning region, a refractive index of the bulk InGaAs is changed to control the oscillation wavelength of the DBR laser.

A strain InGaAs/InGaAs multiple quantum well (MQW) is used as a medium of the optical gain waveguide. Here, the strain InGaAs/InGaAs-MQW is an MQW in which InGaAs having different compositions for applying a compression strain and an elongation strain to the InGaAs material is periodically stacked with a thickness equal to or less than the critical film thickness of the material. As described above, the strain MQW is an MQW that can be regarded as a lattice matching system macroscopically by periodically applying a strain in the opposite direction. In a normal InP-based semiconductor laser, the longest oscillation wavelength is about 1.65 μm, but a wavelength-tunable laser oscillating in a wavelength band of 2 μm can be realized by using a strain MQW (Non Patent Literature 1).

### CITATION LIST

### Non Patent Literature

Non Patent Literature 1: Y. Ueda., et al., “2-um band active distributed Bragg reflector laser for CO₂ gas sensing”, Appl. Phys. Express, 12, 092011 (2019).

### SUMMARY

### Technical Problem

In the current injection type semiconductor wavelength-tunable laser, not only a refractive index change amount necessary for wavelength change but also an optical loss increases as carrier injection into a tuning region increases. This increase in the optical loss in the tuning region increases an optical loss in a laser resonator and decreases a light output. That is, in a current injection type wavelength-tunable laser, a reduction in a light output associated with a wavelength change is a problem.

In a current injection type semiconductor wavelength-tunable laser, a configuration is disclosed in which a semiconductor having an optically active (optical gain) composition is inserted into a part of a semiconductor in a tuning region (Non Patent Literature 1). In this configuration, when carriers are injected into the tuning region, because some injected carriers contribute to optical amplification, a refractive index of the tuning region can be changed and an optical loss caused by the refractive index change can be compensated for. As described above, according to this configuration, it is possible to curb a decrease in a light output accompanying a wavelength change of the current injection type wavelength-tunable laser.

However, since an optically active semiconductor material is introduced into a tuning region made of a bulk semiconductor, there is a problem of increasing a manufacturing load in semiconductor crystal growth. Since a ratio of an optical active region in a laser resonator increases, a problem such as a decrease in the reliability of an element may occur. Solution to Problem

In order to solve the above-described problem, according to embodiments of the present invention, there is provided a wavelength-tunable laser including a substrate, a waveguide layer, and a cladding provided in this order; an active layer disposed in a part of the waveguide layer; a tunable wavelength filter disposed in at least one end region of the waveguide layer; and a barrier region disposed between at least a part of the waveguide layer not including the active layer and the cladding layer.

According to embodiments of the present invention, there is provided a wavelength-tunable laser including a substrate, a waveguide layer, and a cladding provided in this order; an active layer disposed in a part of the waveguide layer; a tunable wavelength filter disposed in at least one end region of the waveguide layer; a first electrode pad for injecting a current into the active layer; a second electrode pad for injecting a current into the tunable wavelength filter; a third electrode pad for injecting a current into at least a part of the waveguide layer not including the active layer or the tunable wavelength filter; and a resistance portion that connects at least one of the second electrode pad and the third electrode pad to the first electrode pad.

According to embodiments of the present invention, there is provided a wavelength-tunable laser module including a wavelength-tunable laser including a substrate, a waveguide layer, and a cladding provided in this order, an active layer disposed in a part of the waveguide layer, and a tunable wavelength filter disposed in at least one end region of the waveguide layer; and a wiring substrate including a first substrate electrode pad for injecting a current into the active layer, a second substrate electrode pad for injecting a current into the tunable wavelength filter, a third substrate electrode pad for injecting a current into at least a part of the waveguide layer not including the active layer or the tunable wavelength filter, and a resistor that connects at least one of the second substrate electrode pad and the third substrate electrode pad to the first substrate electrode pad.

According to embodiments of the present invention, there is provided a method of manufacturing a layer structure of a wavelength-tunable laser including, in order, an n-type substrate, a waveguide layer including an active layer and a bulk core layer, and a p-type cladding layer, the method including a step of growing a semiconductor crystal for the active layer on the n-type substrate; a step of processing the grown semiconductor crystal for the active layer into the active layer; a step of butt-joint growing a semiconductor crystal for the bulk core layer around the active layer; a step of growing an undoped semiconductor crystal on the semiconductor crystal for the bulk core layer; a step of removing at least the undoped semiconductor crystal on the active layer; a step of forming a tunable wavelength filter in at least one end region of the semiconductor crystal for the bulk core layer; and a step of growing a semiconductor crystal for the p-type cladding layer.

### Advantageous Effects

According to embodiments of the present invention, it is possible to provide a wavelength-tunable laser, a wavelength-tunable laser module, and a method of manufacturing a layer structure of a wavelength-tunable laser capable of easily curbing a decrease in a light output.

### BRIEF DESCRIPTION OF THE DRAWINGS

FIG. 1A is a schematic top view illustrating a configuration of a wavelength-tunable laser according to a first embodiment of the present invention.

FIG. 1B is a schematic side sectional view taken along line IB-IB′ of the configuration of the wavelength-tunable laser according to the first embodiment of the present invention.

FIG. 2 is a flowchart for describing the method of manufacturing the layer structure of the wavelength-tunable laser according to the first embodiment of the present invention.

FIG. 3A is a view for describing an effect of the wavelength-tunable laser according to the first embodiment of the present invention.

FIG. 3B is a view for describing an effect of the wavelength-tunable laser according to the first embodiment of the present invention.

FIG. 4 is a diagram for describing an effect of the wavelength-tunable laser according to the first embodiment of the present invention.

FIG. 5A is a schematic side sectional view illustrating an example of a configuration of the wavelength-tunable laser according to the first embodiment of the present invention.

FIG. 5B is a schematic side sectional view illustrating an example of the configuration of the wavelength-tunable laser according to the first embodiment of the present invention.

FIG. 5C is a schematic side sectional view illustrating an example of the configuration of the wavelength-tunable laser according to the first embodiment of the present invention.

FIG. 5D is a schematic side sectional view illustrating an example of the configuration of the wavelength-tunable laser according to the first embodiment of the present invention.

FIG. 5E is a schematic side sectional view illustrating an example of the configuration of the wavelength-tunable laser according to the first embodiment of the present invention.

FIG. 5F is a schematic side sectional view illustrating an example of the configuration of the wavelength-tunable laser according to the first embodiment of the present invention.

FIG. 5G is a schematic side sectional view illustrating an example of the configuration of the wavelength-tunable laser according to the first embodiment of the present invention.

FIG. 5H is a schematic side sectional view illustrating an example of the configuration of the wavelength-tunable laser according to the first embodiment of the present invention.

FIG. 5I is a schematic side sectional view illustrating an example of the configuration of the wavelength-tunable laser according to the first embodiment of the present invention.

FIG. 5J is a schematic side sectional view illustrating an example of the configuration of the wavelength-tunable laser according to the first embodiment of the present invention.

FIG. 5K is a schematic side sectional view illustrating an example of the configuration of the wavelength-tunable laser according to the first embodiment of the present invention.

FIG. 6 is a schematic top view illustrating a configuration of a wavelength-tunable laser according to a second embodiment of the present invention.

FIG. 7 is a schematic top view illustrating a configuration of a wavelength-tunable laser module according to a third embodiment of the present invention.

FIG. 8A is a diagram for describing a configuration of a conventional wavelength-tunable laser.

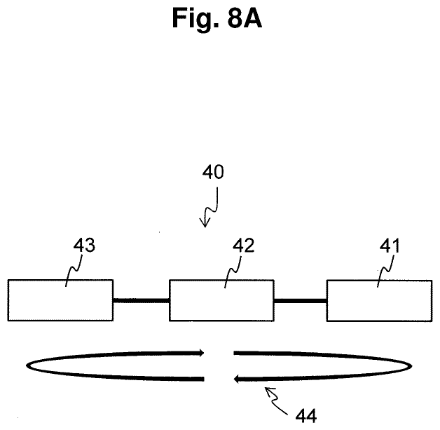

FIG. 8B is a diagram for describing an operation of the conventional wavelength-tunable laser.

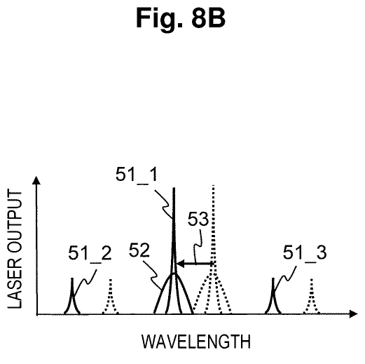

### DETAILED DESCRIPTION OF ILLUSTRATIVE EMBODIMENTS

### First Embodiment

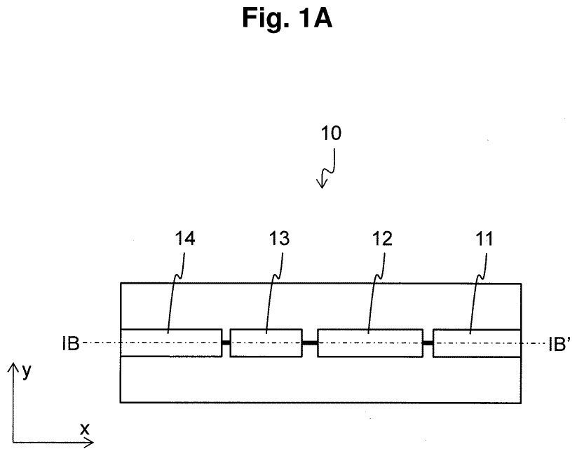

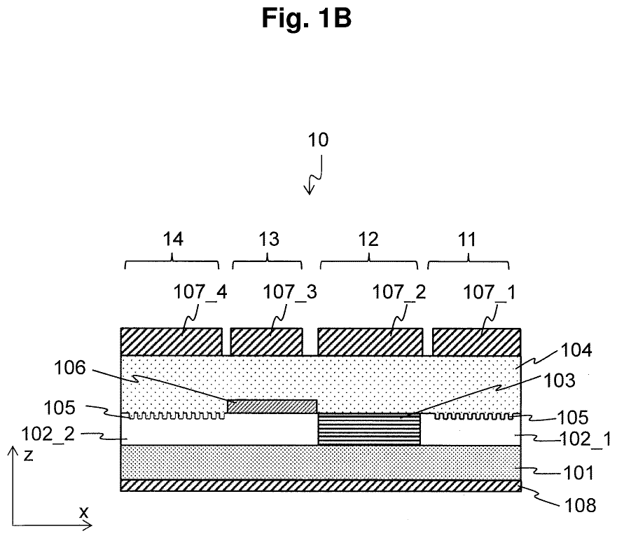

A wavelength-tunable laser according to a first embodiment of the present invention will be described with reference to FIGS. 1A to 4.

### Configuration of Wavelength-Tunable Laser

As illustrated in FIGS. 1A and 1B, a wavelength-tunable laser 10 according to the present embodiment includes, in order in a light guiding direction (in the drawing, an x direction), a first tunable wavelength region (tunable wavelength filter, TWF) 11, an optical gain region 12, a phase adjustment region 13, and a second tunable wavelength region (tunable wavelength filter, TWF) 14.

In the wavelength-tunable laser 10, a DBR is used for the tunable wavelength filter, and the first tunable wavelength region and the second tunable wavelength region are set as a first DBR region 11 and a second DBR region 14, respectively.

A length of the first DBR region 11 is 200 to 300 μm, a length of the optical gain region 12 is 200 to 300 μm, a length of the phase adjustment region 13 is 100 μm, and a length of the second DBR region 14 is 600 μm. Here, the “length” is a length in the light guiding direction.

Each of the first DBR region 11 and the second DBR region 14 includes a first waveguide core layer (bulk core) 102_1, a second waveguide core layer (bulk core) 102_2, a p-type InP cladding 104, and electrodes (DBR electrodes) 107_1 and 107_4 in order in a layer direction (in the drawing, a z direction) on an n-type InP substrate 101.

Here, InGaAs having a composition that lattice-matches InP is used for the first waveguide core layer (bulk core) 102_1 and the second waveguide core layer (bulk core) 102_2.

Here, a diffraction grating 105 is provided between each of the first waveguide core layer (InGaAs bulk core) 102_1 and the second waveguide core layer (InGaAs bulk core) 102_2 and the p-type InP cladding 104. A pitch of the diffraction gratings 105 is determined such that reflection peak wavelengths of the first DBR region 11 and the second DBR region 14 are 2.025 μm. The first DBR region 11 and the second DBR region 14 reflect light having a specific wavelength toward the optical gain region 12.

The optical gain region 12 includes an active layer 103, a p-type InP cladding 104, and an electrode (optical gain electrode) 107_2 in this order in a layer direction (in the drawing, a z direction) on the n-type InP substrate 101.

The active layer 103 is a strain InGaAs/InGaAs multiple quantum well (MQW), and an amount of strain is set such that the peak of a photoluminescence (PL) spectrum is 2.015 μm.

The phase adjustment region 13 includes an InGaAs bulk core (second waveguide core layer) 102_2, a p-type InP cladding 104, and an electrode (phase adjustment electrode) 107_3 in this order in a layer direction (in the drawing, a z direction) on the n-type InP substrate 101. The phase adjustment region 13 finely adjusts a resonator length of a resonator.

In the phase adjustment region 13, a barrier region 106 is provided at a boundary between the InGaAs bulk core (second waveguide core layer) 102_2 and the p-type InP cladding 104. Undoped intrinsic (i)-InP is used for the barrier region 106, and the layer thickness is about 100 nm. Here, the layer thickness may be, for example, 20 to 500 nm.

An n-type electrode 108 is provided on the back surface of the n-type InP substrate.

Hereinafter, a layer including a first waveguide core (bulk core) layer, an active layer, and a second waveguide core (bulk core) layer in this order in the light guiding direction will be referred to as a “waveguide layer”.

As described above, the wavelength-tunable laser according to the present embodiment sequentially includes the substrate, the waveguide layer, and the cladding, and includes the active layer disposed in a part of the waveguide layer, the DBR disposed in the end region of the waveguide layer (the end regions of the first waveguide core layer and the second waveguide core layer), and the barrier region disposed between the waveguide layer and the cladding layer in the phase adjustment region.

### Method of Manufacturing Layer Structure of Wavelength-Tunable Laser

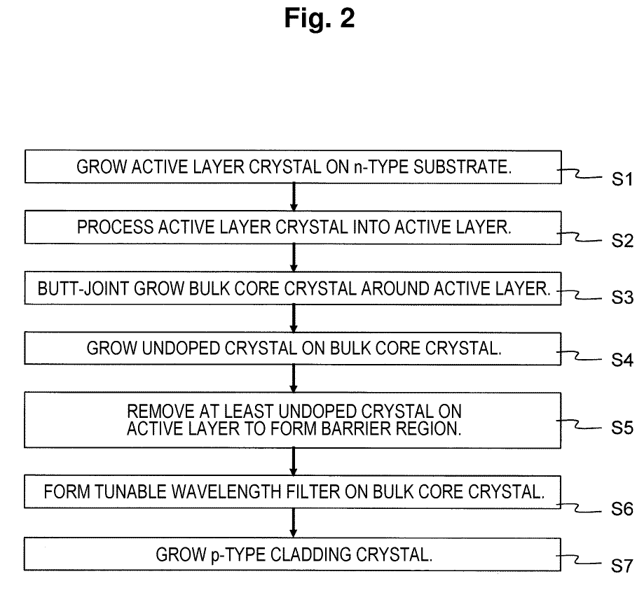

An example of a method of manufacturing a layer structure of the wavelength-tunable laser 10 according to the present embodiment will be described with reference to FIG. 2.

First, a strain InGaAs/InGaAs multiple quantum well, which is an active layer crystal (crystal for the active layer 103) of the optical gain region 12, is grown on the n-type InP substrate 101 (step S1).

Next, the active layer crystal is processed into an active layer through photolithography and etching (step S2).

Next, InGaAs is butt-joint-grown as a bulk core crystal (crystal for the first waveguide core layer 102_1 and the second waveguide core layer 102_2) around the active layer (step S3).

Subsequently, undoped InP (crystal for the barrier region 106) is grown on InGaAs with a thickness of about 100 nm during butt joint growth (step S4).

Next, undoped InP (at least undoped InP on the active layer) other than the barrier region 106 is removed through selective etching to form a barrier region of undoped InP (step S5).

Next, the diffraction grating 105 is formed on the surface of the bulk core crystal in the first DBR region 11 and the second DBR region 14 (step S6).

Finally, a crystal for the p-type InP cladding layer (crystal for the cladding 104) is grown on the active layer crystal, the bulk core crystal, and the barrier region 106 of undoped InP (step S7).

As described above, the layer structure of the wavelength-tunable laser 10 is manufactured.

Processing of a waveguide structure, electrode formation, and the like are performed on the layer structure of the wavelength-tunable laser according to a normal semiconductor laser manufacturing process to manufacture the wavelength-tunable laser 10.

### Operation of Wavelength-Tunable Laser

An operation of the wavelength-tunable laser 10 according to the present embodiment will be described below.

As illustrated in FIG. 1B, since the high-resistance i-InP is disposed as the barrier region 106 immediately above the bulk core (second waveguide core layer) 102_2 of the phase adjustment region 13, a part of a current injected in the phase adjustment region 13 bypasses the bulk core (second waveguide core layer) 102_2 of the phase adjustment region 13 and flows into the optical gain region 12.

As a result, an increase in the resonator loss due to an increase in the carrier density in the bulk core (second waveguide core layer) 102_2 of the phase adjustment region 13 can be compensated for by an increase in an amount of current to the optical gain region 12. As a result, it is possible to curb a decrease in a light output due to phase adjustment.

Here, undoped i-InP is used for the barrier region 106, but Zn, which is a dopant of the p-InP cladding (for example, the p-type concentration is about 1 to 3×1018) 104, diffuses into the undoped i-InP, and the undoped i-InP can become p-InP (for example, the p-type concentration is about 1×1016 to 1×1017). Even in this case, since p-InP (for example, the p-type concentration is about 1×1016 to 1×1017) has a sufficiently low p-type concentration as compared with the p-InP cladding 104, a part of the injected current in the phase adjustment region 13 can be provided to the optical gain region 12 as the high-resistance barrier region 106.

As described above, the barrier region 106 may have a high resistance to such an extent that a part of the injected current can bypass the barrier region 106 to be supplied to the optical gain region 12, and may have, for example, about 1 MΩ to about 10 MΩ, and is desirably about 1 MΩ to about several MΩ.

Fe-doped InP or n-type InP may be used for the barrier region 106. In addition to InP, InAlAs or InGaAlAs may be used.

In the wavelength-tunable laser according to the present embodiment, the tunable wavelength regions 11 and 14 and the phase adjustment region 13 are desirably controlled independently from the viewpoint of wavelength controllability. Therefore, a configuration in which currents are separately injected into the tunable wavelength regions 11 and 14 and the phase adjustment region 13 is desirable.

For example, in the wavelength-tunable laser according to the present embodiment, there is a possibility that an injected current into the phase adjustment region 13 bypasses the barrier region 106, flows into the optical gain region 12, and also flows into the tunable wavelength region 14. As a result, there is a possibility that the control of the tunable wavelength region 14 is affected by the injected current into the phase adjustment region 13, and thus the independence of the control is impaired.

Therefore, by disposing the tunable wavelength region 14 and the phase adjustment region 13 apart from each other, it is possible to prevent an injected current into the phase adjustment region 13 from bypassing the barrier region 106 and flowing into the tunable wavelength region 14. By forming a groove structure for separation between the tunable wavelength region 14 and the phase adjustment region 13, it is possible to curb an injected current into the phase adjustment region 13 from bypassing the barrier region 106 and flowing into the tunable wavelength region 14.

### Effects

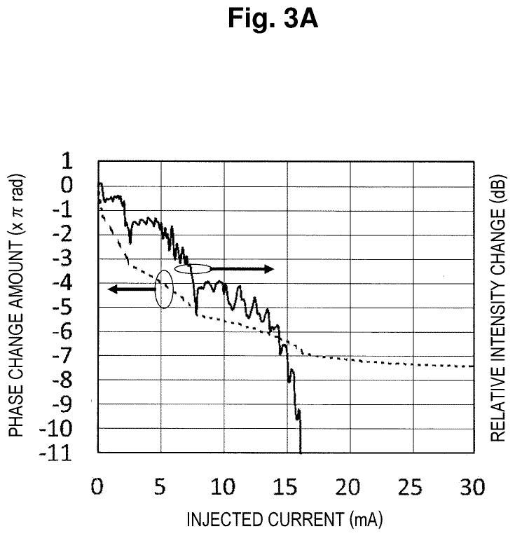

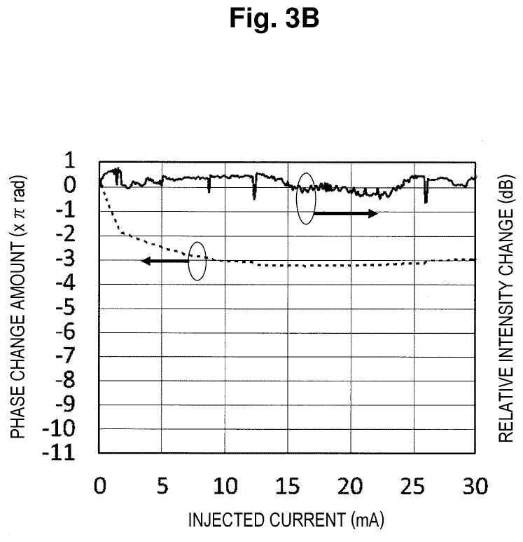

Each of FIGS. 3A and 3B illustrates a phase change (dotted line) and a relative change (solid line) of the light output when an amount of current injected into the phase adjustment region 13 is changed in the conventional structure in which the portion immediately above the bulk core (second waveguide core layer) 102_2 of the phase adjustment region 13 is p-InP and the structure in the present embodiment in which the portion immediately above the bulk core (second waveguide core layer) 102_2 is i-InP.

In a case where the portion immediately above the bulk core (second waveguide core layer) 102_2 of the phase adjustment region 13 is p-InP, when the injected current is increased to 30 mA, the phase changes to −7π rad. The light intensity significantly decreases, and the injected current decreases to −11 dB or less at about 16 mA or more.

On the other hand, when the portion immediately above the bulk core (second waveguide core layer) 102_2 of the phase adjustment region 13 is i-InP, the phase changes to −3π rad, and the light intensity hardly decreases.

As described above, in a case where the portion immediately above the bulk core (second waveguide core layer) 102_2 is i-InP, the phase change per current is small and the relative change in light intensity is also small as compared with the case of p-InP. This is because a part of the current injected into the phase adjustment region 13 flows into the optical gain region 12. In this case, in the wavelength-tunable laser, even if the injected current into the optical gain region 12 increases, the carrier density is fixed, and thus the injected current does not contribute to a change in an optical phase. On the other hand, the injected current into the optical gain region 12 increases a light output.

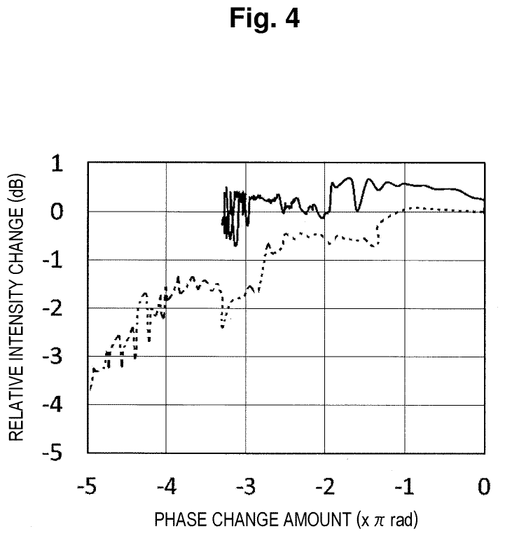

The phase change and the relative change of the light output with respect to the change of an amount of the injected current into the phase adjustment region 13 illustrated in FIGS. 3A and 3B are plotted in a relationship between an amount of the phase change and the light output change as illustrated in FIG. 4. In the drawing, a solid line indicates a relationship in the present embodiment, and a dotted line indicates a relationship in the conventional structure.

In a case where the portion immediately above the bulk core (second waveguide core layer) 102_2 is i-InP, the light output decreases to −4 dB when the phase change is 0 to −5π rad. On the other hand, in a case where the portion immediately above the bulk core (second waveguide core layer) 102_2 is i-InP, the light output hardly decreases when the phase change is 0 to −3π rad.

As described above, in a case where the portion immediately above the bulk core (second waveguide core layer) 102_2 of the phase adjustment region 13 is high-resistance i-InP, an amount of absolute phase change that can be reached is small, but a decrease in the light output per phase change can be curbed.

In the wavelength-tunable laser according to the present embodiment, by supplying a part of an injected current into the tunable wavelength region or the phase adjustment region to the optical gain region 12, it is possible to compensate for the optical loss in the tunable wavelength region or the phase adjustment region into which the current is injected. As a result, it is possible to curb a reduction in a light output of the wavelength-tunable laser.

### Modification Examples

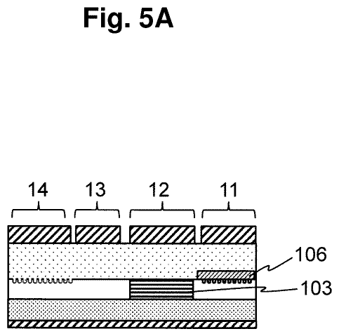

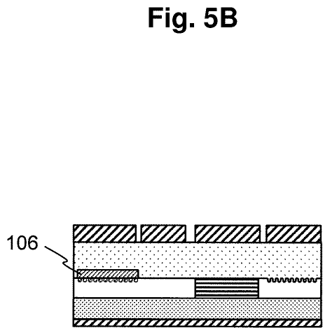

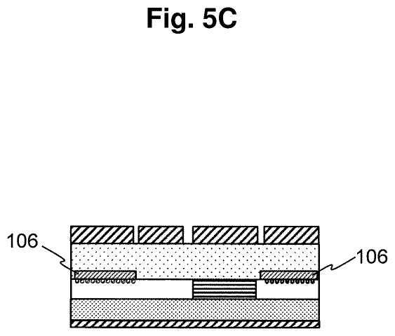

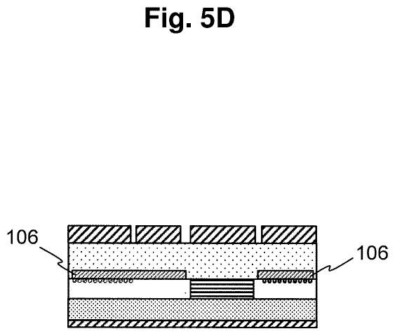

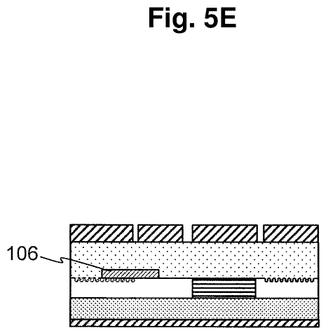

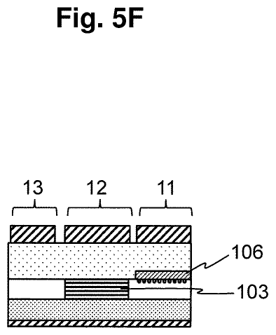

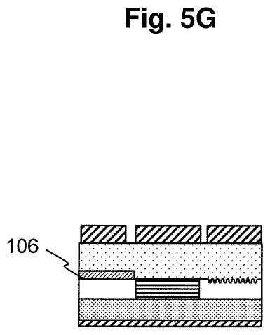

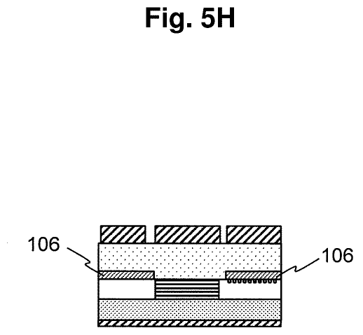

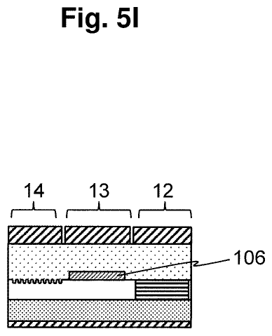

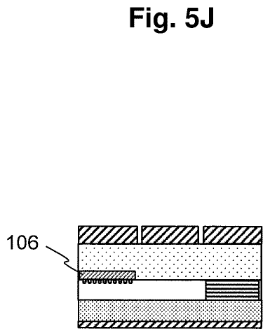

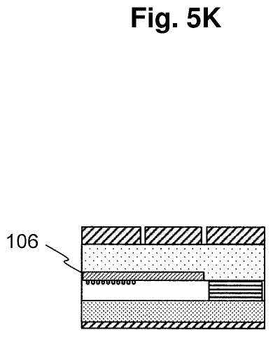

In the present embodiment, an example in which the barrier region 106 is disposed in the phase adjustment region 13 has been described, but the present disclosure is not limited thereto. As illustrated in FIGS. 5A and 5B, the barrier region 106 may be disposed in the first DBR region 11 or the second DBR region 14, and as illustrated in FIG. 5C, the barrier region 106 may be disposed in both the first DBR region 11 and the second DBR region 14. Alternatively, as illustrated in FIG. 5D, the barrier region 106 may be disposed in the phase adjustment region 13, the first DBR region 11, and the second DBR region 14. Alternatively, as illustrated in FIG. 5E, the barrier region 106 may be disposed in a part of the phase adjustment region 13 and a part of the second DBR region 14.

In this manner, the barrier region 106 may be disposed at least in a part of a region other than the optical gain region 12.

Here, in the control of the wavelength-tunable laser, it is necessary to inject an equivalent current to both the DBR regions 11 and 14.

Therefore, in a case where the barrier region 106 is disposed in the DBR regions 11 and 14, it is desirable to employ a configuration in which the barrier region 106 is disposed in both the first DBR region 11 and the second DBR region 14 as illustrated in FIGS. 5C and 5D in order to inject an equivalent current to both the DBR regions 11 and 14.

As illustrated in FIGS. 5C to 5E, in the configuration in which the barrier region 106 is disposed in one of the first DBR region 11 and the second DBR region 14, an amount of current may be adjusted such that equivalent currents are injected into both the tunable wavelength regions (DBR regions) 11 and 14.

In the present embodiment, an example in which the DBRs are provided at both ends of the wavelength-tunable laser has been described, but the present invention is not limited thereto, and a configuration in which a DBR is provided at one end and a reflector having no wavelength dependency such as a cleavage surface mirror is provided at the other end may be employed. For example, as illustrated in FIGS. 5F to 5H, a configuration in which the first DBR region 11, the optical gain region 12, and the phase adjustment region 13 are provided in this order may be employed. Alternatively, as illustrated in FIGS. 5I to 5K, a configuration in which the optical gain region 12, the phase adjustment region 13, and the second DBR region 14 are provided in this order may be employed.

As described above, even in the configuration in which the DBR is provided at one end of the wavelength-tunable laser, the barrier region 106 may be disposed at least in a part of the region other than the optical gain region.

### Second Embodiment

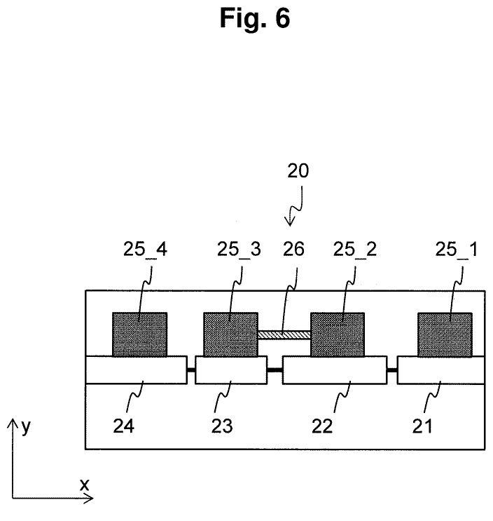

A wavelength-tunable laser according to a second embodiment of the present invention will be described with reference to FIG. 6.

### Configuration of Wavelength-Tunable Laser

As illustrated in FIG. 6, a wavelength-tunable laser 20 according to the present embodiment includes, in order in a light guiding direction (in the drawing, an×direction), a first DBR region 21, an optical gain region 22, a phase adjustment region 23, and a second DBR region 24, and includes an electrode pad 25_1, an electrode pad 25_2, an electrode pad 25_3, and an electrode pad 25_4 electrically connected to respective electrodes.

Here, a configuration of the wavelength-tunable laser in the layer direction is similar to that of the conventional current injection type wavelength-tunable laser.

The electrode pad 25_2 of the optical gain region 22 is connected to the electrode pad 25_3 of the phase adjustment region 23 via a resistance portion 26 with high resistance (about 1 MΩ to about 10 MΩ). The resistance portion 26 is made of an electrode material such as metal.

For the connection with high resistance using the resistance portion 26, a configuration in which a width of a low-resistance material (such as gold) is small or a thickness thereof is small, which is the same as the electrode pads 25_2 and 25_3, is used. Alternatively, a high resistance material (tungsten or the like) may be used. Here, an amount of current from the phase adjustment region 23 to the optical gain region 22 can be adjusted by using a value of the electric resistance of the resistance portion 26.

In the wavelength-tunable laser according to the present embodiment, a part of an injected current into the tunable wavelength region or the phase adjustment region is supplied to the optical gain region via the resistance portion connecting the pads, and thus it is possible to compensate for the optical loss in the tunable wavelength region or the phase adjustment region into which the current is injected. As a result, it is possible to curb a reduction in a light output of the wavelength-tunable laser.

In the present embodiment, an example in which the electrode pad 25_2 of the optical gain region 22 and the electrode pad 25_3 of the phase adjustment region 23 are connected via the resistance portion 26 has been described, but the present invention is not limited thereto. The electrode pad 25_2 of the optical gain region 22 and any of the other electrode pads may be connected via the resistance portion 26.

For example, the electrode pad 25_2 of the optical gain region 22 may be connected to the electrode pad 25_1 or 25_4 of the first DBR region 21 or the second DBR region 24 via the resistance portion 26. Alternatively, the electrode pad 25_2 of the optical gain region 22 may be connected to both the electrode pads 25_1 and 25_4 of the first DBR region 21 and the second DBR region 24 via the resistance portion 26. Alternatively, the electrode pad 25_2 of the optical gain region 22 may be connected to all of the other electrode pads 25_1, 25_3, and 25_4.

In this case, it is desirable that equivalent currents are injected into the first DBR region 21 and the second DBR region 24. For example, it is desirable to employ a configuration in which the electrode pad 25_2 of the optical gain region 22 may be connected to both the electrode pads 25_1 and 25_4 of the first DBR region 21 and the second DBR region 24 via the resistance portion 26.

In the configuration in which the electrode pad 25_2 of the optical gain region 22 is connected to one of the electrode pads 25_1 and 25_4 of the first DBR region 21 and the second DBR region 24 via the resistance portion 26, an amount of current may be adjusted such that equivalent currents are injected into both the electrode pads 25_1 and 25_4.

In the present embodiment, the DBRs are provided at both ends of the wavelength-tunable laser, but the present invention is not limited thereto, and a configuration in which the DBR is provided at one end and a reflector having no wavelength dependency such as a cleavage surface mirror is provided at the other end may be employed. For example, a configuration in which the first DBR region 21, the optical gain region 22, and the phase adjustment region 23 are provided in this order may be employed. In this case, one or both of the electrode pad 25_1 of the first DBR region 21 and the electrode pad 25_3 of the phase adjustment region 23 may be connected to the electrode pad 25_2 of the optical gain region 22 via the resistance portion 26.

Alternatively, a configuration in which the optical gain region 22, the phase adjustment region 23, and the second DBR region 24 are provided in this order may be employed. In this case, one or both of the electrode pad 25_3 of the phase adjustment region 23 and the electrode pad 25_4 of the second DBR region 24 may be connected to the electrode pad 25_2 of the optical gain region 22 via the resistance portion 26.

### Third Embodiment

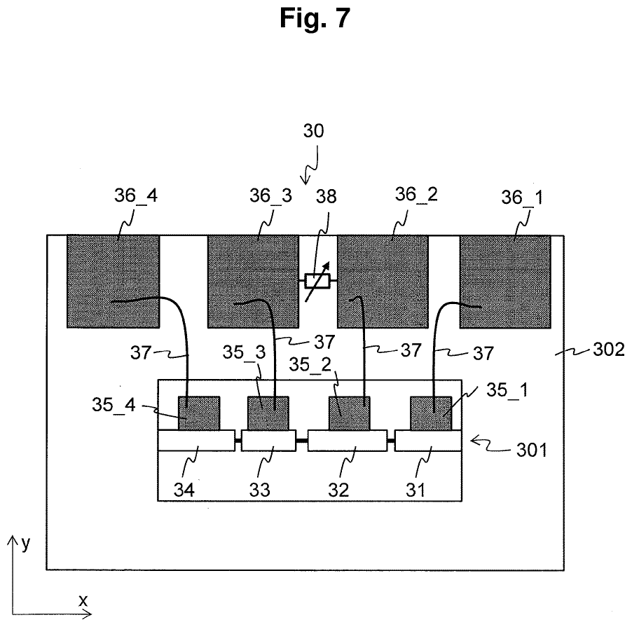

A wavelength-tunable laser module according to a third embodiment of the present invention will be described with reference to FIG. 7.

### Configuration of Wavelength-Tunable Laser Module

In a wavelength-tunable laser module 30 according to the present embodiment, as illustrated in FIG. 7, a wavelength-tunable laser 301 is mounted on a wiring substrate 302, and electrode pads 35_1, 35_2, 35_3, and 35_4 of a first DBR region 31, an optical gain region 32, a phase adjustment region 33, and a second DBR region 34 in the wavelength-tunable laser 301 are connected to respective substrate electrode pads 36_1, 36_2, 36_3, and 36_4 of a wiring substrate 302 via wires 37.

Here, the substrate electrode pad 36_2 of the wiring substrate 302 connected to the optical gain region 32 is connected to the substrate electrode pad 36_3 of the wiring substrate 302 connected to the phase adjustment region 33 with high resistance via a resistor 38.

The resistor 38 has a high resistance of about 1 MΩ to about 10 MΩ. Alternatively, if the resistor 38 is a variable resistor, an amount of current from the phase adjustment region 33 to the optical gain region 32 can be adjusted at the stage of mounting the wavelength-tunable laser 301 on the wiring substrate 302.

According to the wavelength-tunable laser module according to the present embodiment, a part of an injected current into the tunable wavelength region or the phase adjustment region of the wavelength-tunable laser is supplied to the optical gain region via the resistor connecting the substrate electrodes of the wiring substrate, and thus it is possible to compensate for an optical loss in the tunable wavelength region or the phase adjustment region into which the current is injected. As a result, it is possible to curb a reduction in a light output of the wavelength-tunable laser.

In the present embodiment, the example in which the substrate electrode pad 36_2 and the substrate electrode pad 36_3 are connected via the resistor 38 has been described, but the present invention is not limited thereto. The substrate electrode pad 36_2 and any of the other electrode pads may be connected via the resistor 38.

For example, the substrate electrode pad 36_2 may be connected to the substrate electrode pad 36_1 or the substrate electrode pad 36_4 via the resistor 38. Alternatively, the substrate electrode pad 36_2 may be connected to both of the substrate electrode pads 36_1 and 36_4 via the resistor 38. Alternatively, the substrate electrode pad 36_2 may be connected to all of the other substrate electrode pads 36_1, 36_3, and 36_4.

In this case, it is desirable that equivalent currents are injected into the first DBR region 31 and the second DBR region 34. For example, it is desirable that the substrate electrode pad 36_2 is connected to both the substrate electrode pads 36_1 and 36_4 via the resistor 38.

In the configuration in which the substrate electrode pad 36_2 is connected to one of the substrate electrode pads 36_1 and 36_4 via the resistor 38, an amount of current may be adjusted such that equivalent currents are injected into both the electrode pads 36_1 and 36_4.

In the present embodiment, the DBRs are provided at both ends of the wavelength-tunable laser, but the present invention is not limited thereto, and a configuration in which the DBR is provided at one end and a reflector having no wavelength dependency such as a cleavage surface mirror is provided at the other end may be employed. For example, a configuration in which the first DBR region 31, the optical gain region 32, and the phase adjustment region 33 are provided in this order may be employed. In this case, one or both of the substrate electrode pad 36_1 and the substrate electrode pad 36_3 may be connected to the substrate electrode pad 36_2 via the resistor 38.

Alternatively, a configuration in which the optical gain region 32, the phase adjustment region 33, and the second DBR region 34 are provided in this order may be employed. In this case, one or both of the substrate electrode pad 36_3 and the substrate electrode pad 36_4 may be connected to the substrate electrode pad 36_2 via the resistor 38.

In the embodiment of the present invention, an example in which a DBR is used as the tunable wavelength region (tunable wavelength filter) has been described, but the present invention is not limited thereto, and a ring resonator, a sampling diffraction grating Bragg reflector, or the like may be used, and a wavelength filter that returns light having a specific wavelength to the optical gain region with wavelength selectivity may be used. In this case, in a method of manufacturing a layer structure of a wavelength-tunable laser, a structure of a tunable wavelength filter such as a ring resonator may be formed in a bulk core crystal instead of a DBR (diffraction grating).

In the embodiment of the present invention, an example in which the oscillation wavelength band of the wavelength-tunable laser is set to about 2.0 μm and the wavelength-tunable laser is used for CO₂ gas sensing has been described, but the present invention is not limited thereto. The wavelength-tunable laser may be used for sensing ammonia or water. The oscillation wavelength band may be set to about 1.6 to 1.8 μm such that the wavelength-tunable laser is used for sensing CH₄ or HCl, and the oscillation wavelength band may be set to about 2.1 to 2.4 μm such that the wavelength-tunable laser is used for sensing N₂O or CO.

The oscillation wavelength band of the wavelength-tunable laser may be set to about 1.3 to 1.55 μm such that the wavelength-tunable laser is used as a laser for optical communication.

In the wavelength-tunable laser, since the influence of free electrons of InGaAs of the bulk core is larger and the optical loss is larger in the wavelength band of 2.0 μm or more than the wavelength band of 1.3 to 1.55 μm, the effect of the embodiment of the present invention is large.

In the embodiment of the present invention, an example of using an InP-based semiconductor as a semiconductor has been described, but other semiconductors such as a GaAs-based semiconductor, a SiGe-based semiconductor, and a GaN-based semiconductor may be used. GaAs, Si, sapphire, or the like may be used for the substrate in addition to InP.

In the embodiment of the present invention, examples of the structure, dimensions, materials, and the like of each component have been described in the configuration of the wavelength-tunable laser and the wavelength-tunable laser module, the method of manufacturing a layer structure, and the like, but the present invention is not limited thereto. It is sufficient that functions and effects of the wavelength-tunable laser and the wavelength-tunable laser module are exhibited.

### INDUSTRIAL APPLICABILITY

Embodiments of the present invention relates to a wavelength-tunable laser, a wavelength-tunable laser module, and a method of manufacturing a layer structure of a wavelength-tunable laser, and can be applied to an optical communication light source and a gas sensing light source.

### Reference Signs List

| | |
|---|---|
| 10 | Wavelength-tunable laser |
| 101 | Substrate |
| 103 | Active layer |
| 104 | Cladding |
| 105 | Tunable wavelength filter |
| 106 | Barrier region |

1-7. (canceled)

8. A method of manufacturing a layer structure of a wavelength-tunable laser including, in order, an n-type substrate, a waveguide layer including an active layer and a bulk core layer, and a p-type cladding layer, the method comprising:
growing a semiconductor crystal for the active layer on the n-type substrate;
processing the grown semiconductor crystal for the active layer into the active layer;
butt-joint growing a semiconductor crystal for the bulk core layer around the active layer;
growing an undoped semiconductor crystal on the semiconductor crystal for the bulk core layer;
removing at least the undoped semiconductor crystal on the active layer;
forming a tunable wavelength filter in at least one end region of the semiconductor crystal for the bulk core layer; and
growing a semiconductor crystal for the p-type cladding layer.

9. The method according to claim 8, wherein the undoped semiconductor crystal comprises intrinsic InP.

10. The method according to claim 8, wherein the tunable wavelength filter comprises a distributed Bragg reflector (DBR).

11. The method according to claim 8, wherein the active layer comprises a strain InGaAs/InGaAs multiple quantum well (MQW).

12. The method according to claim 8, further comprising:
forming a diffraction grating between the bulk core layer and the p-type cladding layer in the at least one end region where the tunable wavelength filter is formed.

13. The method according to claim 8, wherein the n-type substrate comprises InP, and wherein the bulk core layer comprises InGaAs having a composition that lattice-matches InP.

14. The method according to claim 8, wherein growing the undoped semiconductor crystal comprises growing the undoped semiconductor crystal to a thickness of about 20 nm to about 500 nm.

15. A wavelength-tunable laser comprising:
a substrate;
a waveguide layer over the substrate;
a cladding over the waveguide layer;
an active layer in a part of the waveguide layer; and
a tunable wavelength filter in at least one end region of the waveguide layer in a direction along which light is to be guided.

16. The wavelength-tunable laser according to claim 15, further comprising a barrier region between the waveguide layer and the cladding, the barrier region disposed on at least a part of the waveguide excluding the active layer.

17. The wavelength-tunable laser according to claim 16, wherein
the barrier region is configured to supply a current which bypasses the barrier region to the active layer.

18. The wavelength-tunable laser according to claim 16, wherein
the barrier region is made of a first semiconductor material,
the cladding is made of a second semiconductor material, and
a doping concentration of the barrier region is lower than a doping concentration of the cladding.

19. The wavelength-tunable laser according to claim 17, wherein
the barrier region is made of a first semiconductor material,
the cladding is made of a second semiconductor material, and
a doping concentration of the barrier region is lower than a doping concentration of the cladding.

20. The wavelength-tunable laser according to claim 15, further comprising
a first electrode pad for injecting a current into the active layer;
a second electrode pad for injecting a current into the tunable wavelength filter;
a third electrode pad for injecting a current into at least a part of the waveguide layer not including the active layer or the tunable wavelength filter; and
a resistance portion that connects at least one of the second electrode pad and the third electrode pad to the first electrode pad.

21. A wavelength-tunable laser module comprising:
a wiring substrate, and
a wavelength-tunable laser according to claim 15, the wavelength-tunable laser mounted on the wiring substrate,
wherein the wiring substrate includes:
a first substrate electrode pad for injecting a current into the active layer of the wavelength-tunable laser,
a second substrate electrode pad for injecting a current into the tunable wavelength filter of the wavelength-tunable laser,
a third substrate electrode pad for injecting a current into at least a part of the waveguide layer not including the active layer or the tunable wavelength filter, and
a resistor that connects at least one of the second substrate electrode pad and the third substrate electrode pad to the first substrate electrode pad.

22. The wavelength-tunable laser module according to claim 21, wherein the resistor is a variable resistor.
